(19) United States
(12) Patent Application Publication
(10) Pub. No.: US 2009/0167096 A1
(43) Pub. Date: Jul. 2, 2009

(54) Pulse Width Modulation For Precision Energy/Power Dumping

(75) Inventors: Witold Sosnowski, Anderson, SC (US); Joseph Gill, Evans, GA (US); Patrick Warden, Grovetown, GA (US); Oliver A. Bell, Aiken, SC (US)

Correspondence Address: HARNESS, DICKEY & PIERCE, P.L.C., P.O. BOX 828, BLOOMFIELD HILLS, MI, 48303, US

(73) Assignee: TEXTRON INC., Providence, RI (US)

(21) Appl. No.: 11/965,776

(22) Filed: Dec. 28, 2007

(51) Int. Cl. H01H 47/00; G01R 19/00

(52) U.S. Cl. 307/113; 307/126; 324/76.11

(57) ABSTRACT

Accordingly, an energy dumping system for an electric component system is provided. The energy dumping system includes a power consuming element that consumes excess energy of the electric component system and dissipates the excess energy as heat. A solid state switch selectively permits energy of the electric component system to flow across the power consuming element. A control module is operable to monitor a voltage of the electric component system and apply a pulse width modulated (PWM) signal to the solid state switch to selectively control energy of the electric component system to flow across the power consuming element.

### FIELD

The present disclosure relates to a method and system for controlling energy levels in an electric component system.

### BACKGROUND

The statements in this section merely provide background information related to the present disclosure and may not constitute prior art.

Storing of regenerative energy created by a motor of a vehicle is well known to the art. For example, regenerative energy can be created when a driver of the vehicle steps on the brakes or when the vehicle travels down a hill. In such cases, the motor turns into a generator to produce electrical energy. This is essentially free energy that would normally be wasted. However, hybrid and electric vehicles store the regenerative energy for later use.

Electric vehicle components must be tested prior to installation or during development to ensure proper functionality. Dynamometers measure the performance of the components and provide loading and drive torque to the UUT. A test scenario includes a unit under test which includes a motor controller and a motor which applies braking torque to resist a driving force of the dynamometer. When the torque is applied, the motor becomes a generator for electrical energy. In a vehicle, batteries traditionally absorb the generated energy. In a test environment, the use of lead-acid batteries to supply power and absorb the energy is undesirable. Their charge must be managed and water levels checked by technicians. Batteries also have the potential to perform inconsistently depending on factors such as state of charge, useable life, etc. The inconsistencies may provide for skewed test results. Eliminating the batteries would improve costs, required maintenance, and safety of the test environment.

### SUMMARY

Accordingly, an energy dumping system for an electric component system is provided. The energy dumping system includes a power consuming element that consumes excess energy of the electric component system and dissipates the excess energy as heat. A solid state switch selectively permits energy of the electric component system to flow across the power consuming element. A control module is operable to monitor a voltage of the electric component system and apply a pulse width modulated (PWM) signal to the solid state switch to selectively control energy of the electric component system to flow across the power consuming element.

In other features, a method of dumping excess energy in an electric component system is provided. The method comprises: monitoring a voltage of the electric component system; selectively controlling a solid state switch via a pulse with modulated signal based on the voltage; and passing excess energy of the electric component system across a consuming element via the solid state switch when the voltage exceeds a threshold voltage.

In still other features, an electric component test system is provided. The system includes a power source that supplies a direct current. A motor electrically connects with and is powered by the power source to generate electrical energy. A control module monitors the energy supplied by the motor and generates a pulse width modulated signal when the energy exceeds a threshold. A solid state switch is controlled by the pulse width modulated signal to selectively pass energy across an absorbing element from the motor and capacitor.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a schematic illustration of an energy dumping control system, according to various embodiments of the present disclosure.

FIG. 2 is a schematic illustration of a control module used for energy dumping, according to various embodiments of the present disclosure.

### DETAILED DESCRIPTION

The following description is merely exemplary in nature and is not intended to limit the present disclosure, application, or uses. It should be understood that throughout the drawings, corresponding reference numerals indicate like or corresponding parts and features. As used herein, the term module refers to an application specific integrated circuit (ASIC), an electronic circuit, a processor (shared, dedicated, or group) and memory that execute one or more software or firmware programs, a combinational logic circuit, or other suitable components that provide the described functionality.

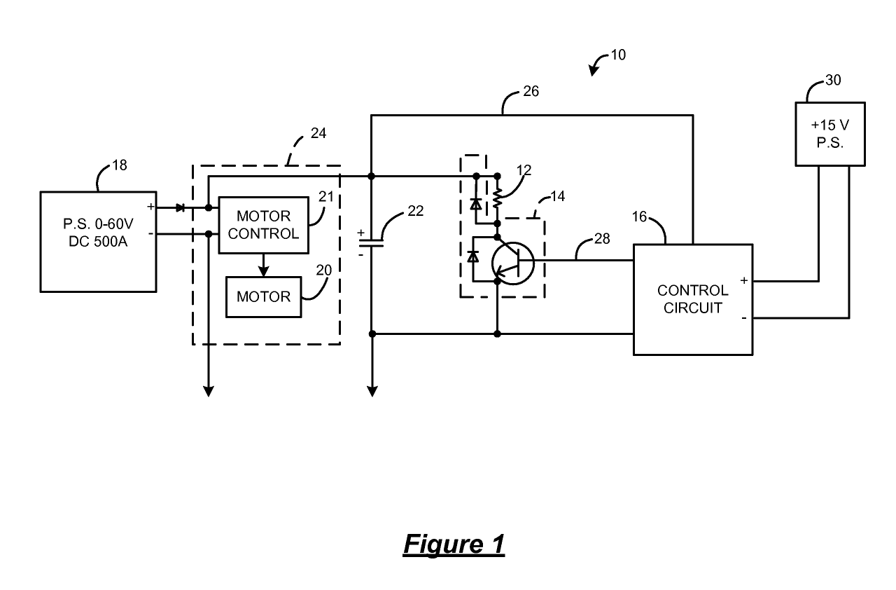

In order to control energy levels of electric component systems, pulse width modulation (PWM) technology can be used to regulate system voltage. More particularly, when an adjustable voltage threshold of the system is exceeded, PWM technology can be used to instantaneously dump excess energy in the form of heat by power consuming elements. It is appreciated that PWM technology can be employed in various applications where precision dumping of electric energy can be beneficial. For example, FIG. 1 is a schematic diagram of a regenerative energy dumping system 10 for electric powertrain dynamometers. System 10 includes: a large high-power resistor 12, a solid state switch 14, and a control module 16. Control module 16 monitors system 10 for excess energy and controls solid state switch 14 such that the excess energy can be dissipated via resistor 12.

More particularly, power source 18, motor 20, and motor controller 21 serve as an electric powertrain that performs both motoring and generating functions. Power source 18 can be a DC power source. Motor controller 21 can be an AC or a DC drive controller. Motor 20 and motor controller 21 can be collectively referred to as a unit under test (UUT) 24. Capacitor 22 connects in parallel to motor 20 and stores electric charge to filter out ripple.

Solid state switch 14 selectively permits energy to pass across resistor 12 from a power bus 26 of UUT 24 when a rising voltage of the power bus 26 indicates that regenerative operation has begun. For example, when solid state switch 14 is turned ON, resistor 12 consumes excess electrical energy and dissipates it as heat. Switch 14 can be any known solid state switch including, but not limited to, an insulated-gate bipolar transistor (IGBT), a power metal oxide semiconductor field-effect transistor (MOSFET), and a silicon controlled rectifier (SCR). In the illustrated embodiment, an IGBT is used.

Control module 16 monitors the voltage on bus 26 of UUT 24. When the voltage rises during regenerative operation to a predetermined threshold, control module 16 turns on switch 14 to allow resistor 12 to consume excess energy and dissipate the excess energy as heat. Control module 16 applies a pulse width modulated signal to switch 14 via an electrical connection 28. The pulse width modulated signal permits resistor 12 to consume more or less energy depending on the mechanical (and, thus, electrical) demands of system 10. Fast reaction and precise voltage control are necessary to make the transfer of energy seamless. A power supply 30 provides power to control module 16.

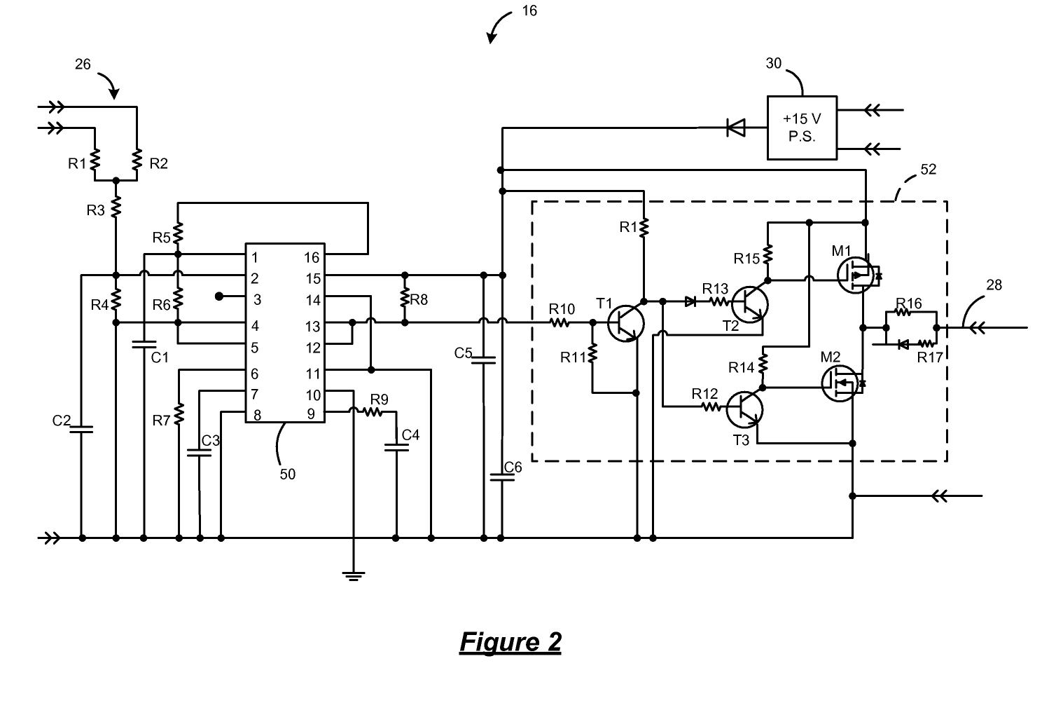

Referring now to FIG. 2, an exemplary control module 16 is shown. Control module 16 includes a pulse width modulator integrated circuit 50 and a switch driver 52. Pulse width modulator integrated circuit 50 outputs a pulse width modulated signal, wherein the width of the output pulse varies with the magnitude of the signal at the control input. In the illustrated embodiment, a type LM3524 pulse width modulator is used. As can be appreciated, other forms of pulse width modulator integrated circuits may be employed, or alternatively, controller module 16 may be constructed from discrete components in a known manner.

Terminal 2 of pulse width modulator integrated circuit 50 is the control input. Control input is provided via a voltage divider network comprising resistors R1, R2, and R3. A comparison reference signal is present at the reference input terminal 1. The reference signal is generated by a reference supply voltage internal to the pulse width modulator integrated circuit 50 and output via terminal 16. Pulse width modulator integrated circuit 50 includes an oscillator (not shown). The oscillator's frequency is set by an external resistor R7 and capacitor C3 via terminals 6 and 7. The oscillator's output provides the signals for triggering an internal flip-flop (not shown) which directs the PWM information to outputs at terminals 12 and 13. Power is supplied to the pulse width modulator 50 via terminal 15. Terminal 10 shuts down the pulse width modulator integrated circuit 50, thus preventing battery charging. The remaining terminals are connected in a conventional fashion. Further description of the type LM3524 pulse width modulator integrated circuit can be found in existing literature.

The output of pulse width modulator integrated circuit 50 is electrically connected to switch driver 52. Switch driver 52 amplifies the output signal via a two stage amplification system comprising a plurality of NPN transistors T1, T2, and T3. Enhancement p-channel MOSFET M1 and enhancement n-Channel MOSFET M2 are switched on and off to generate an enhanced pulse width modulated signal. The enhanced signal is output to control switch 14 of FIG. 1 via electrical connection 28.

Those skilled in the art can now appreciate from the foregoing description that the broad teachings of the present invention can be implemented in a variety of forms. Therefore, while this invention has been described in connection with particular examples thereof, the true scope of the invention should not be so limited since other modifications will become apparent to the skilled practitioner upon a study of the drawings, the specification and the following claims.

What is claimed is:

1. An energy dumping system for an electric component system, comprising:
a power consuming element that consumes excess energy of the electric component system and dissipates the excess energy as heat;
a solid state switch that selectively permits energy of the electric component system to flow across the power consuming element; and
a control module operable to monitor a voltage of the electric component system and apply a pulse width modulated (PWM) signal to the solid state switch to selectively control energy of the electric component system to flow across the power consuming element.

2. The energy dumping system of claim 1 wherein the power consuming element is a high-power resistor.

3. The energy dumping system of claim 1 wherein the control module monitors the voltage of the electric component system and applies the PWM signal to the solid state switch when the voltage exceeds an adjustable threshold.

4. The energy dumping system of claim 1 wherein the control module comprises a PWM integrated circuit and a switch driver.

5. The energy dumping system of claim 1 wherein the solid state switch is at least one of an insulated-gate bipolar transistor (IGBT), a power metal oxide semiconductor field-effect transistor (MOSFET), and a silicon controlled rectifier (SCR).

6. A method of dumping excess energy in an electric component system, comprising:
monitoring a voltage of the electric component system;
selectively controlling a solid state switch via a pulse with modulated signal based on the voltage; and
passing excess energy of the electric component system across a consuming element via the solid state switch when the voltage exceeds a threshold voltage.

7. The method of claim 6 further comprising preventing energy from the electric component system from passing across the absorbing element via the solid state switch when the voltage is below a threshold.

8. The method of claim 6 wherein the monitoring comprises monitoring the voltage of the electric component system and generating the pulse width modulated signal based on the voltage using a pulse width modulator integrated circuit.

9. The method of claim 8 further comprising amplifying the pulse width modulated signal via a plurality of transistors.

10. The method of claim 6 further comprising applying a braking torque to resist a driving force of a motor of the electric component system.

11. The method of claim 10 further comprising operating a motor of the electric component system in a regenerative braking mode.

12. The method of claim 6 further comprising dissipating excess energy as heat via the consuming element.

13. An electric component test system, comprising:
a power source that supplies a direct current;
a motor electrically connected with and powered by the power source to generate electrical energy;
a control module that monitors the energy supplied by the motor and generates a pulse width modulated signal when the energy exceeds a threshold; and
a solid state switch that is controlled by the pulse width modulated signal to selectively pass energy across an absorbing element from the motor and capacitor.

14. The system of claim 13 wherein the control module comprises a pulse width modulation integrated circuit.

15. The system of claim 13 wherein the control module comprises a switch driver.

16. The system of claim 13 wherein the consuming element is a high-power resistor.

17. The system of claim 13 wherein the solid state switch is at least one of an insulated-gate bipolar transistor (IGBT), a power a power metal oxide semiconductor field-effect transistor (MOSFET), and a silicon controlled rectifier (SCR).
